(19) United States
(12) Patent Application Publication
(10) Pub. No.: US 2013/0120013 A1
(43) Pub. Date: May 16, 2013

(54) TEST CARRIER AND METHOD OF ASSEMBLY OF TEST CARRIER

(71) Applicants: Takashi FUJISAKI, Gunma (JP); Kiyoto NAKAMURA, Miyagi (JP)

(72) Inventors: Takashi FUJISAKI, Gunma (JP); Kiyoto NAKAMURA, Miyagi (JP)

(21) Appl. No.: 13/672,051

(22) Filed: Nov. 8, 2012

(30) Foreign Application Priority Data
Nov. 16, 2011 (JP) 2011-250539

(51) Int. Cl. G01R 1/04; B32B 25/00

(52) U.S. Cl. CPC G01R 1/0408; B32B 25/00
USPC 324/756.02; 156/60

(57) ABSTRACT

A test carrier which enables a reduction of cost to be achieved. The test carrier 10 comprises: a base film 40 which holds a die 90; and a film-shaped cover film 70 which is laid over the base film 40 and covers the die 90, the cover film 70 has a self-adhesiveness and is more flexible than the base film 40.

### TECHNICAL FIELD

The present invention relates to a test carrier to which a die chip is temporarily mounted for testing an integrated circuit or other electronic circuit which is formed in a die and to a method of assembly of the same.

The present application claims priority based on Japanese Patent Application No. 2011-250539 of a Japanese patent application which was filed on Nov. 16, 2011. The content which was described in that application is incorporated into the present application by reference and forms part of the description of the present application.

### BACKGROUND ART

Known in the art is a test carrier which has sandwiches a die between a base member and a cover member under reduced pressure and is returned to atmospheric pressure in that state so as to hold the die between the base member and the cover member (for example, see PLT 1). In this test carrier, to secure the air-tightness of the space in which the die is held, a UV curing type binder is applied between the base member and the cover member.

### CITATIONS LIST

### Patent Literature

PLT 1: Japanese Patent Publication No. 2011-128072 A1

### SUMMARY OF INVENTION

### Technical Problem

To assemble a test carrier, a reduced pressure chamber to which a vacuum pump is connected, a device for applying a UV curing type binder, a UV emitting device for curing the binder, etc. become necessary, so there was the problem that higher cost of the test carrier is invited.

The technical problem of the present invention is to provide a test carrier and a method of assembly of the same which can reduce the cost.

### Solution to Problem

[1] A test carrier according to the present invention is a test carrier comprising: a first member which holds an electronic device; and a film-shaped second member which is laid over the first member and covers the electronic device, wherein at least one of the second member and the first member has a self-adhesiveness and the second member is more flexible than the first member.

[2] In the above invention, the second member may be composed of a material which has a self-adhesiveness.

[3] In the above invention, the second member may be composed of a silicone rubber.

[4] In the above invention, at least one of the second member and the first member may have a layer which has a self-adhesiveness.

[5] Further, a method of assembly of a test carrier according to the present invention comprises: preparing a first member and a film-shaped second member which has a self-adhesiveness and which is more flexible than the first member; placing an electronic device on the second member; and placing the first member on the second member to sandwich the electronic device between the first member and the second member.

[6] In the above invention, the second member may be composed of a silicone rubber.

[7] Further, a method of assembly of a test carrier according to the present invention comprises: preparing a first member which has a self-adhesiveness and a film-shaped second member which is more flexible than the first member; placing an electronic device on the first member; and placing the second member on the first member to sandwich the electronic device between the first member and the second member.

[8] In the above invention, the first member may have a layer which has a self-adhesiveness.

### Advantageous Effects of Invention

According to the present invention, the self-adhesiveness of at least one of the second member and the first member is utilized to join the first member and the second member, and the tension of the flexible second member is utilized to push the electronic device against the first member. For this reason, a pressure reducing chamber, a binder applying device, a UV irradiating device, or other complicated device becomes unnecessary, so a lower cost of the test carrier can be achieved.

### BRIEF DESCRIPTION OF DRAWINGS

FIG. 1 is a flow chart which shows a part of the process of production of a device in an embodiment of the present invention.

FIG. 2 is a disassembled perspective view of a test carrier in an embodiment of the present invention.

FIG. 3 is a cross-sectional view of a test carrier in an embodiment of the present invention.

FIG. 4 is a disassembled cross-sectional view of a test carrier in an embodiment of the present invention.

FIG. 5 is an enlarged view of a part V of FIG. 4.

FIG. 6 is a disassembled cross-sectional view which shows a first modification of a test carrier in an embodiment of the present invention.

FIG. 7 is a disassembled cross-sectional view which shows a second modification of a test carrier in an embodiment of the present invention.

FIG. 8 is a cross-sectional view which shows a modification of a cover member in the present invention.

FIG. 9 is a cross-sectional view which shows a modification of a base member in the present invention.

FIG. 10 is a flow chart which shows a method of assembly of a test carrier in an embodiment of the present invention.

### DESCRIPTION OF EMBODIMENTS

Below, an embodiment of the present invention will be explained based on the drawings.

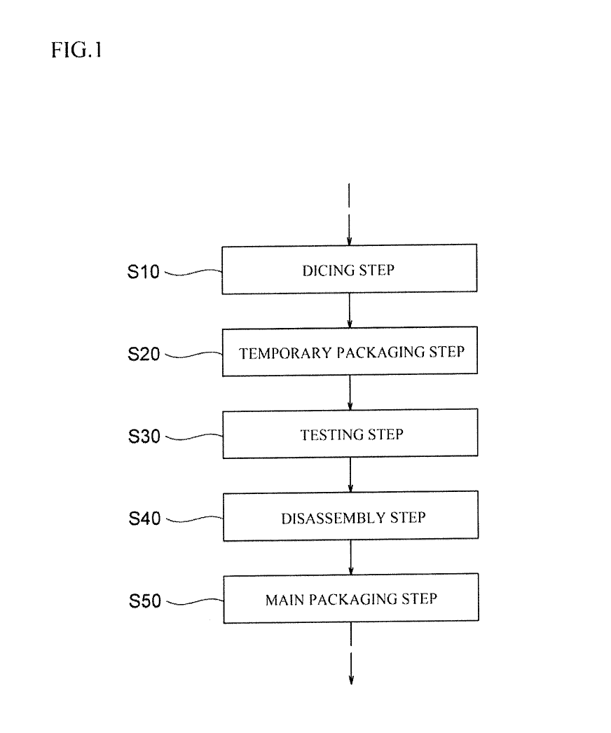

FIG. 1 is a flow chart which shows a part of a process of production of a device in the present embodiment.

In the present embodiment, after a semiconductor wafer is diced (after FIG. 1, step S10) and before final packaging (before step S50), electronic circuits which are built into the die 90 are tested (steps S20 to S40).

In the present embodiment, first, a carrier assembly device (not shown) is used to temporarily mount the die 90 in a test carrier 10 (step S20). Next, through this test carrier 10, the die 90 and the test system (not shown) are electrically connected so as to test the electronic circuits which are built into the die 90 (step S30). Further, after this test ends, the die 90 is taken out from the test carrier 10 (step S40), then this die 90 is packaged by main packaging to thereby complete the device as a final product (step S50).

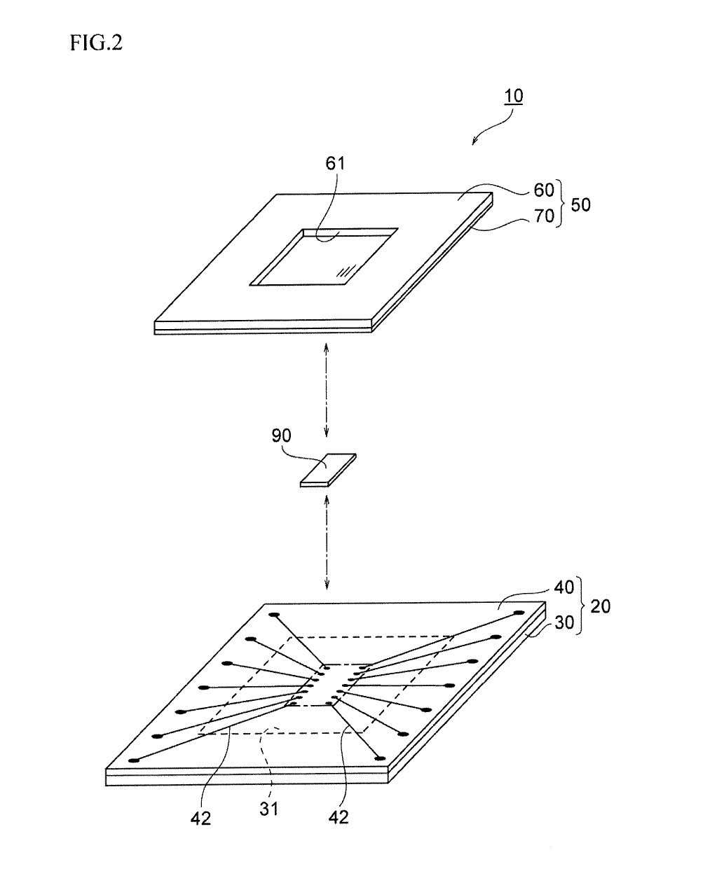

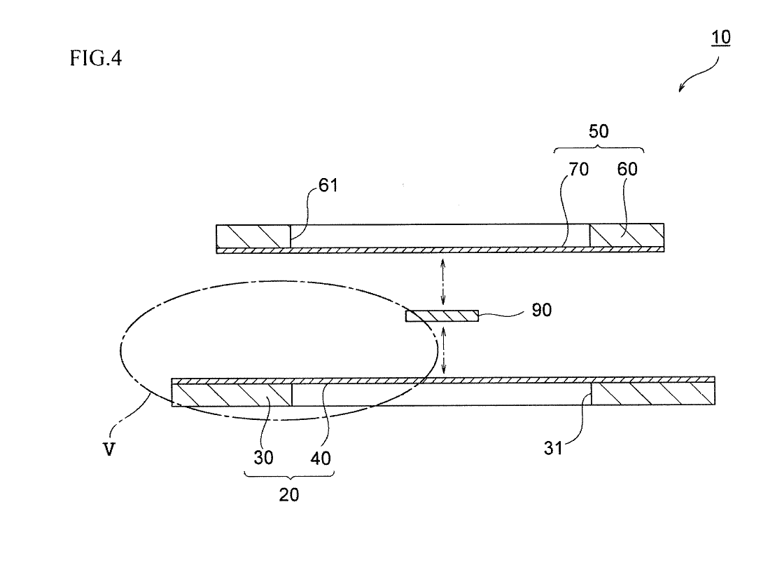

Below, the configuration of the test carrier 10 to which the die 90 is temporarily mounted (provisionally packaged) in the present embodiment will be explained while referring to FIG. 2 to FIG. 9.

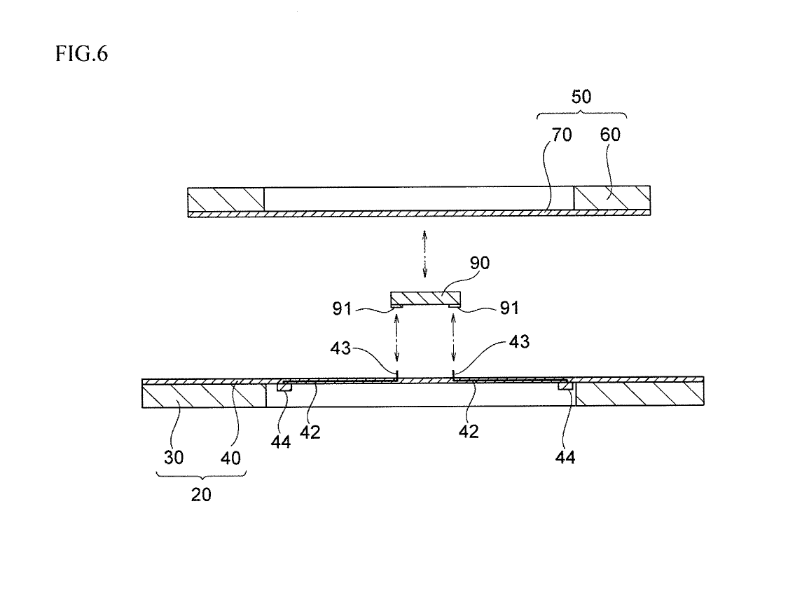

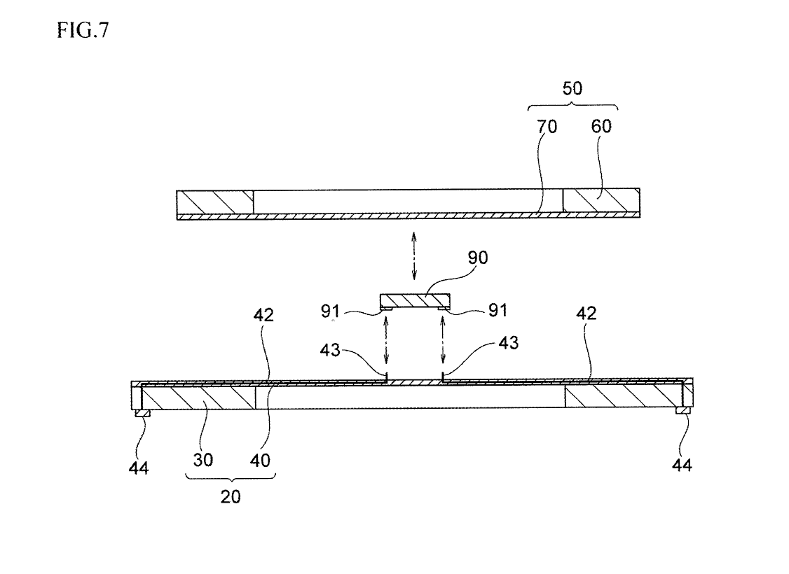

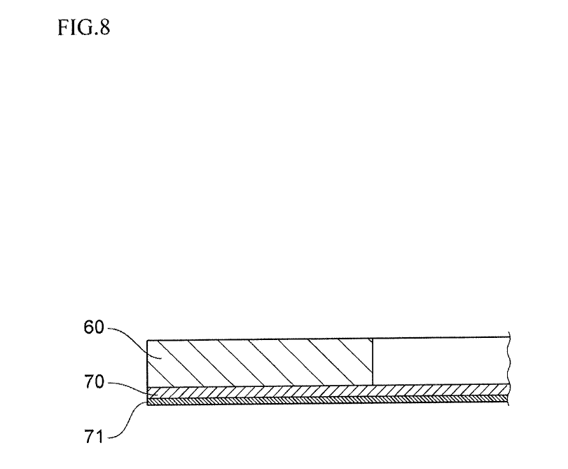

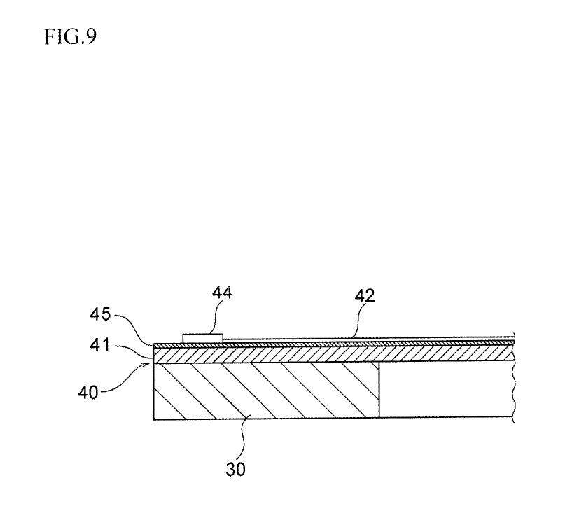

FIG. 2 to FIG. 5 are views which show the test carrier in the present embodiment, FIG. 6 and FIG. 7 are views which show modifications of the test carrier in the present embodiment, FIG. 8 is a view which shows a modification of a cover member in the present embodiment, and FIG. 9 is a view which shows a modification of a base member in the present embodiment.

The test carrier 10 in the present embodiment, as shown in FIG. 2 to FIG. 4, comprises: a base member 20 on which a die 90 is carried; and a cover member 50 which is laid on the base member 20 and which covers the die 90. This test carrier 10 sandwiches the die 90 between the base member 20 and the cover member 50 so as to hold the die 90. The die 90 in the present embodiment is equivalent to one example of the electronic device in the present invention.

The base member 20 comprises a base frame 30 and a base film 40. The base film 40 in the present embodiment is equivalent to one example of the first member in the present invention.

The base frame 30 is a rigid board which has a high rigidity (at least a rigidity higher than the base film 40) and is formed with an opening 31 at the center. As the material which forms this base frame 30, for example, a polyamide imide resin, ceramic, glass, etc. may be illustrated.

On the other hand, the base film 40 is a film which has flexibility and is attached to the entire surface of the base frame 30, including the center opening 31, through a binder (not shown). In this way, in the present embodiment, since the base film 40 which has flexibility is attached to the base frame 30 which has a high rigidity, the handling ability of the base member 20 is improved.

Note that, it is also possible to omit the base frame 30 and configure the base member 20 by only the base film 40. Alternatively, it is also possible to omit the base film 40 and use a rigid printed circuit board as the base member 20, the rigid printed circuit board is the base frame on which the interconnect patterns 43 is formed and which does not have the opening 31.

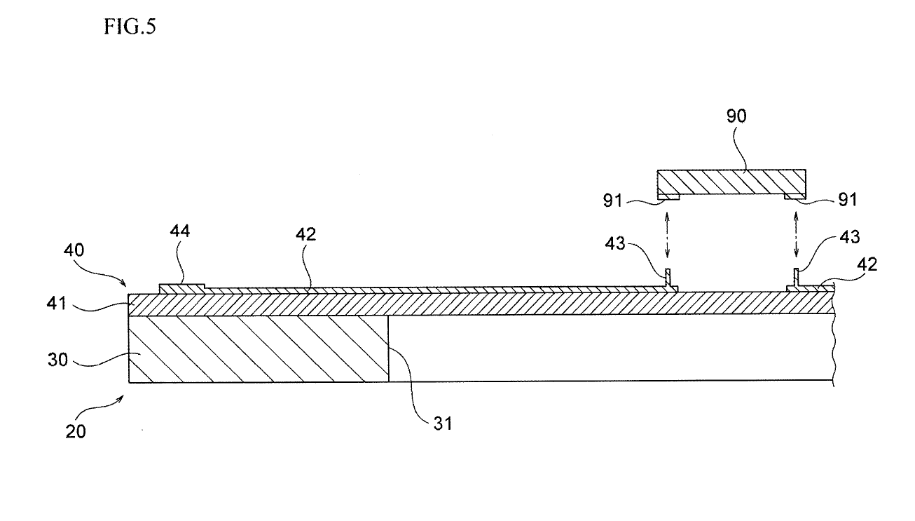

As shown in FIG. 5, this base film 40 has a film body 41 and interconnect patterns 42 which are formed on the surface of the film body 41. The film body 41, for example, comprises a polyimide film etc. Further, the interconnect patterns 42 are, for example, formed by etching copper film which is laminated on the film body 41. Note that, the film body 41 may be laminated with a cover layer which for example comprises a polyimide film so as to protect the interconnect patterns 42 or a so-called multilayer flexible printed circuit board may be used as the base film 40.

As shown in FIG. 5, a bump 43 designed to electrically contact an electrode pad 91 of the die 90 is provided at one end of each interconnect pattern 42. This bump 43 is, for example, composed of copper (Cu), nickel (Ni), etc. and, for example, is formed by the semiadditive method on the end of the interconnect pattern 42.

On the other hand, an external terminal 44 is formed at the other end of the interconnect pattern 42. At the time of the test of the electronic circuits which are built into the die, such external terminals 44 are electrically contacted by contactors of the test system (not shown) whereby the die 90 is electrically connected through the test carrier 10 to the test system.

Note that, the interconnect patterns 42 are not limited to the above configuration. While not particularly shown, for example, part of the interconnect patterns 42 may be formed on the surface of the base film 40 by ink jet printing in real time. Alternatively, all of the interconnect patterns 42 may be formed by ink jet printing.

Further, FIG. 5 only shows two electrode pads 91, but in actuality, the die 90 is formed with a large number of the electrode pads 91, and the base film 40 is provided with a large number of bumps 43 so as to correspond to the electrode pads 91.

Further, the positions of the external terminals 44 are not limited to the above positions. For example, as shown in FIG. 6, the external terminals 44 may also be formed on the bottom surface of the base film 40. Alternatively, as shown in FIG. 7, the external terminals 44 may be formed on the bottom surface of the base frame 30. In the case of the example which is shown in FIG. 7, through holes and interconnect patterns are formed in the base frame 30 to thereby electrically connect the interconnect patterns 42 and the external terminals 44.

Further, while not particularly shown, in addition to the base film 40, the cover film 70 may be formed with the interconnect patterns 42 or external terminals 44, and the cover frame 60 may be formed with the external terminals 44.

Returning to FIG. 2 to FIG. 4, the cover member 50 comprises the cover frame 60 and the cover film 70. The cover film 70 in the present embodiment is equivalent to one example of the second member in the present invention.

The cover frame 60 is a rigid board which has a high rigidity (at least a rigidity higher than the base film 40) and which is formed with an opening 61 at its center. In the present embodiment, this cover frame 60 also, like the above-mentioned base frame 30, is composed of a polyimide resin, ceramic, glass, etc.

On the other hand, the cover film 70 is a film which is composed of an elastic material which has a Young's modulus lower than the base film 40 (low hardness) and which has a self-adhesiveness (tackiness). As the specific material which forms this cover film 70, for example, a silicone rubber, urethane, etc. may be mentioned. Here, the “self-adhesiveness” means the property of being able to stick to another object without using a tackifier, binder or adhesive. In the present embodiment, instead of the conventional pressure reduction system, the self-adhesiveness of this cover film 70 is utilized to join the base member 20 and the cover member 50.

Note that, as shown in FIG. 8, the cover film 70 may be composed of a material which has a lower Young's modulus than the base film 40 and the surface of the film 70 may be coated with a silicone rubber etc. to form a self-adhesive layer 71 and thereby give the cover film 70 a self-adhesiveness.

Alternatively, the cover film 70 may be composed of a material which has a lower Young's modulus than the base film 40 and, as shown in FIG. 9, the surface of the base film 40 may be coated with a silicone rubber etc. to form a self-adhesive layer 45 and thereby give the base film 40 a self-adhesiveness.

Note that, both the cover film 70 and the base film 30 may have a self-adhesiveness.

Returning to FIG. 2 to FIG. 4, the cover film 70 is adhered to the entire surface of the cover frame 60, including the center opening 61, by a binder (not shown). In the present embodiment, a flexible cover film 70 is adhered to the high rigidity cover frame 60, so an improvement in the handling ability of the cover member 50 is achieved. Note that, the cover member 50 may also comprise only the cover film 70.

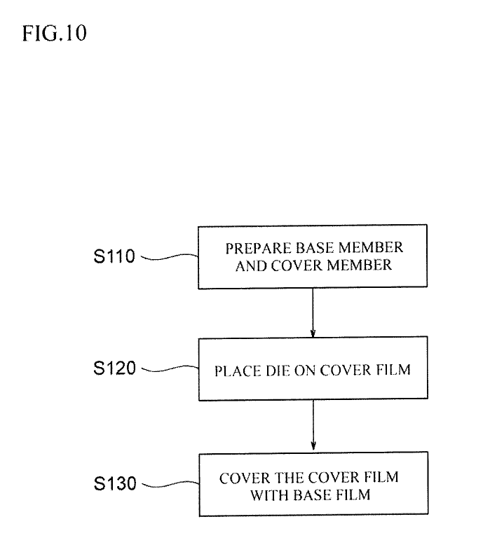

The above explained test carrier 10 is assembled as follows. FIG. 10 shows a method of assembly of the test carrier 10 in the present embodiment.

First, in step S110 of FIG. 10, the base member 20 and the cover member 50 of the above-mentioned configurations are prepared.

Next, in step S120 of FIG. 10, the cover member 50 is turned over, the cover film 70 is positioned on the cover frame 60, then, the die 90 is placed on the cover film 70 in a posture with the electrode pads 91 facing upward.

At this time, in the present embodiment, as explained above, the cover film 70 has a self-adhesiveness, so by just placing the die 90 on the cover film 70, the die 90 can be provisionally fixed to the cover film 70. As opposed to this, when the cover film is not provided with a self-adhesiveness, an electrostatic chuck or other device for provisionally fixing the die 90 in place becomes necessary.

Note that, as shown in FIG. 9, when the base film 40 is given a self-adhesiveness, in this step S120, the die 90 is placed on the base film 40.

Next, in step S130 on FIG. 10, the base member 20 is laid over the cover member 50 to sandwich the die 90 between the base film 40 and the cover film 70.

At this time, in the present embodiment, the cover film 70 has a self-adhesiveness, so by just the base film 40 and the cover film 70 being brought into close contact, they are bonded and therefore the base member 20 and the cover member 50 are integrally joined.

Further, in the present embodiment, the cover film 70 is more flexible than the base film 40 and the tension of the cover film 70 rises by exactly the amount of thickness of the die 90. The tension of this cover film 70 causes the die 90 to be pushed against the base film 40, so positional deviation of the die 90 can be prevented.

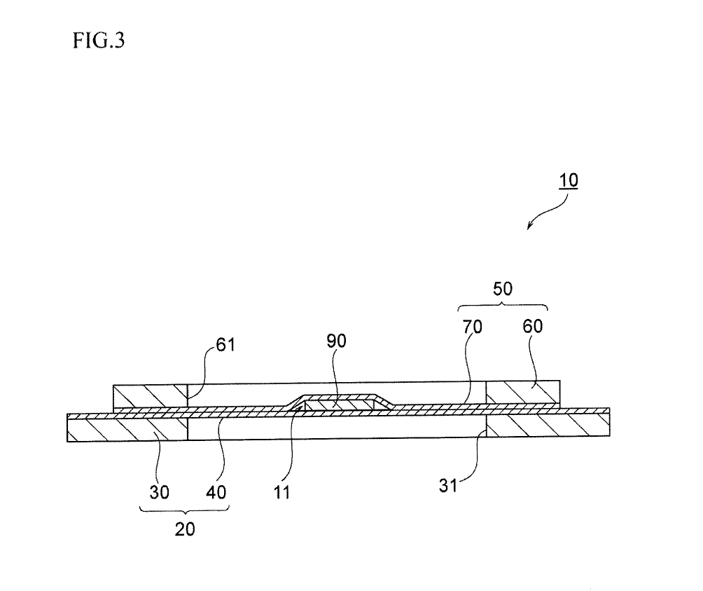

For this reason, in the present embodiment, no pressure reducing chamber is required for reducing the pressure of the holding space 11 (see FIG. 3) which holds the die 90 between the base film 40 and the cover film 70.

Further, in the present embodiment, along with pressure reduction of the holding space 11 becoming unnecessary, the binder applying device for applying a UV curing type binder for securing air-tightness of the holding space 11 and the UV irradiating device for curing the binder also become unnecessary.

Therefore, in the present embodiment, no complicated devices are required when assembling the test carrier 10, so a reduction in cost of the test carrier 10 can be achieved.

Further, in the present embodiment, the base member 20 and the cover member 50 do not have a binder applied between them, so when recycling test carrier 10 from which the die 90 has been taken out in step S40 of FIG. 1, the step of washing the base member 20 or the cover member 50 can be eliminated and a further reduction of cost can be achieved.

Note that, as shown in FIG. 9, when the base film 40 is given a self-adhesiveness, in this step S130, the cover member 50 is laid over the base member 20 on which the die 90 is carried.

The test carrier 10 which has been assembled in the above way is transported to a not particularly shown test system where the contactors of the test system electrically contact the external terminals 44 of the test carrier 10, the test system and the electronic circuits of the die 90 are electrically connected through the test carrier 10, and the electronic circuits of the die 90 are tested. At this time, the base film 40 is preferably pushed toward the die 90 so as to make the bumps 43 of the base film 40 and the electrode pads 91 of the die 90 reliably electrically connect.

Step S110 of FIG. 10 in the present embodiment is equivalent to one example of the first step in the present invention, step S120 of the same figure in the present embodiment is equivalent to one example of the second step in the present invention, while step S130 in the same figure in the present embodiment is equivalent to one example of the third step in the present invention.

Note that, the above explained embodiment was described to facilitate understanding of the present invention and was not described for limiting the present invention. Therefore, the elements which were disclosed in the embodiment include all design changes and equivalents falling under the technical scope of the present invention.

### REFERENCE SIGNS LIST

10 . . . test carrier

11 . . . holding space

20 . . . base member

30 . . . base frame

31 . . . center opening

40 . . . base film

41 . . . film body

42 . . . interconnect pattern

43 . . . bump

44 . . . external terminal

45 . . . self-adhesive layer

50 . . . cover member

60 . . . cover frame

61 . . . center opening

70 . . . cover film

71 . . . self-adhesive layer

90 . . . die

91 . . . electrode pad

1. A test carrier comprising:
a first member which holds an electronic device; and
a film-shaped second member which is laid over the first member and covers the electronic device, wherein
at least one of the second member and the first member has a self-adhesiveness, and
the second member is more flexible than the first member.

2. The test carrier as set forth in claim 1, wherein the second member is composed of a material which has a self-adhesiveness.

3. The test carrier as set forth in claim 2, wherein the second member is composed of a silicone rubber.

4. The test carrier as set forth in claim 1, wherein at least one of the second member and the first member has a layer which has a self-adhesiveness.

5. A method of assembly of a test carrier comprising:
preparing a first member and a film-shaped second member which has a self-adhesiveness and which is more flexible than the first member;
placing an electronic device on the second member; and
placing the first member on the second member to sandwich the electronic device between the first member and the second member.

6. The method of assembly of a test carrier as set forth in claim 5, wherein the second member is composed of a silicone rubber.

7. The method of assembly of a test carrier comprising:
preparing a first member which has a self-adhesiveness and a film-shaped second member and which is more flexible than the first member;
placing an electronic device on the first member; and
placing the second member on the first member to sandwich the electronic device between the first member and the second member.

8. The method of assembly of a test carrier as set forth in claim 7, wherein the first member has a layer which has a self-adhesiveness.
